(19) United States
(12) Patent Application Publication
(10) Pub. No.: US 2013/0192660 A1
(43) Pub. Date: Aug. 1, 2013

(54) DENSE RECEIVER ARRAY WITH BYPASS ELEMENT

(71) Applicant: Brad Siskavich, Amherst, NH (US)

(72) Inventor: Brad Siskavich, Amherst, NH (US)

(21) Appl. No.: 13/739,898

(22) Filed: Jan. 11, 2013

Related U.S. Application Data
(60) Provisional application No. 61/585,394, filed on Jan. 11, 2012.

(51) Int. Cl. H01L 23/46; H01L 31/052; H01L 31/02

(52) U.S. Cl. CPC H01L 23/46; H01L 31/02021; H01L 31/052
USPC 136/246; 136/244; 257/621

(57) ABSTRACT

This disclosure describes embodiments of a receiver component that can support a plurality of photovoltaic devices, which collectively are useful to generate electricity from sunlight. The receiver component can comprise a substrate that integrates one or more bypass elements (e.g., a diode) and a cooling mechanism coupled to the substrate to dissipate thermal energy by dispersing a cooling fluid thereon. In this manner, embodiments of the receiver component combine in a single package the features necessary to maintain performance of the photovoltaic devices, e.g., to achieve sufficient electrical output while reducing costs and manufacturing time.

### CROSS-REFERENCE TO RELATED APPLICATIONS

This application claims the benefit of priority to U.S. Provisional Patent Application Ser. No. 61/585,394, filed on Jan. 11, 2012 and entitled “Dense Receiver Array Substrate with Integrated Bypass Diode.” The content of this application is incorporated herein by reference in its entirety.

### BACKGROUND

1. Technical Field

The subject matter of this disclosure relates to solar energy technology, and in one or more embodiments to structures that mount devices that generate electrical power in response to light in energy conversion systems, e.g., concentrator photovoltaic (“CPV”) systems and modules.

2. Description of Related Art

Photovoltaic devices convert solar energy (or “sunlight”) into electricity. The rate of conversion of sunlight to electricity depends on the available area of the photovoltaic devices. Thus, photovoltaic devices that operate at levels of efficiency that are higher than other photovoltaic devices are able to achieve a higher rate of conversion for the same area. In one example, silicon-based photovoltaic devices have a level of efficiency of about 17% (i.e., these cells can convert 17% of the sunlight they receive into electricity).

Concentrator photovoltaic cells (also “CPV cells”) can generate electricity at a relatively higher level of efficiency than these silicon-based photovoltaic devices. CPV cells often comprise materials, e.g., gallium arsenide and/or germanium, in several layers with multiple junctions. This construction affords the CPV cells with levels of efficiency that are greater than the levels of efficiency of silicon-based photovoltaic devices. For example, multi junction CPV cells often exhibit levels of efficiency of greater than 40% because these devices can convert a greater portion of the solar spectrum into electricity.

These high levels of efficiency make multi junction photovoltaic devices advantageous for use in energy conversions systems. These systems often arrange hundreds (and/or even thousands) of photovoltaic devices in large arrays to capture and convert sunlight to electricity. Unfortunately, high material and manufacturing costs can prohibit implementation of multi junction photovoltaic devices in the large numbers necessary to allow energy conversion systems to generate electricity at adequate costs metrics. One solution to reduce the overall cost, however, is to concentrate sunlight from a large area onto a much smaller area which comprises the multi junction photovoltaic devices (e.g., the CPV cells). Concentrating the sunlight in this matter enables the multi junction photovoltaic devices to operate at levels of efficiency that are relatively greater than silicon-based photovoltaic devices. Because of the improvements in efficiency, the system requires fewer CPV cells to generate comparable amounts of electricity.

Concentrating systems, also known as concentrator photovoltaic (CPV) systems, may concentrate light using a number of different configurations. In one configuration, the system arranges lenses (e.g., refractive lenses) in an array. The lenses focus sunlight onto a corresponding array of CPV cells (also, a “cell receiver assembly (CRA)). In another configuration, the system includes a set of reflective mirrors that reflect a large area of sunlight onto a corresponding array of CPV cells (also called a “dense receiver array (“DRA”)). The DRA is smaller than the CRA because the DRA can incorporate the CPV cells onto a single substrate. However, although use of this single substrate can result in cost savings (e.g., on materials) as compared to the CRA, the DRA arrangement creates additional challenges associated with heat dissipation and, in one example, the need to include additional elements, e.g., by-pass diodes, because of the close packing density of CPV cells on the single substrate. Moreover, many DRAs lack the ability to arrange the CPV cells with sufficient density (i.e., to closely pack the array of CPV cells) to limit efficiency loss due to exposure of non-generating areas of the CPV cells to sunlight while also maintaining acceptable thermal performance.

### SUMMARY

This disclosure describes improvements to CPV systems and, in particular, to DRAs to provide adequate exposure of the solar reactive areas of photovoltaic devices, while maintaining adequate heat dissipation and electrical conduction. These improvements allow CPV systems that implement embodiments of the proposed components to convert solar energy to electricity more efficiently and cost-effectively. In one embodiment, the components incorporate one or more bypass elements (e.g., a diode) and a cooling mechanism within a single device to enable reliable but low-cost manufacturing processes. This disclosure also contemplates a substrate and a cell receiver assembly that supports the substrate, e.g., for use in concentrator photovoltaic (“CPV”) systems and modules.

As set forth in more detail below, examples of the substrate include an integrated bypass diode. The substrate can also support a plurality of photovoltaic devices (e.g., CPV cells) and, in other examples, chips, semiconductor chips, solar chips, etc. Construction of the substrate can position the photovoltaic devices to vary the configuration, e.g., to overlap with one or more adjacent photovoltaic devices to form a “shingled” pattern or configuration. These configurations maximize exposure of the solar sensitive portions of the photovoltaic devices to sunlight. In one embodiment, the components can comprise a CPV cell, a substrate manufactured to integrate the CPV cell and internally incorporate bypass elements, and a back metal layer (and/or array) designed to integrate with a cooling mechanism, e.g., a metal cooling fluid distribution plate.

### BRIEF DESCRIPTION OF THE DRAWINGS

Reference is now made briefly to the accompanying drawings, in which:

FIG. 1 depicts a schematic diagram of an exemplary embodiment of a receiver component that can secure and position photovoltaic devices in a energy conversion system;

FIG. 2 depicts a schematic, cross-section diagram of an exemplary embodiment of a receiver component with a layered structure;

FIG. 3 depicts a side, cross-section view of an exemplary embodiment of a receiver component that positions the photovoltaic devices in a shingled configuration;

FIG. 4 depicts an example of a flow pattern for cooling fluid in the receiver component of FIG. 3;

FIG. 5 depicts a bottom view of the receiver component of FIG. 4;

FIG. 6 depicts a side, cross-section view of an exemplary embodiment of a receiver component that positions photovoltaic devices in a planar configuration; and

FIG. 7 depicts a top, perspective view of an exemplary embodiment of a receiver component that can arrange a plurality of photovoltaic devices in an array, e.g., a dense receiver array.

Where applicable like reference characters designate identical or corresponding components and units throughout the several views, which are not to scale unless otherwise indicated.

### DETAILED DISCUSSION

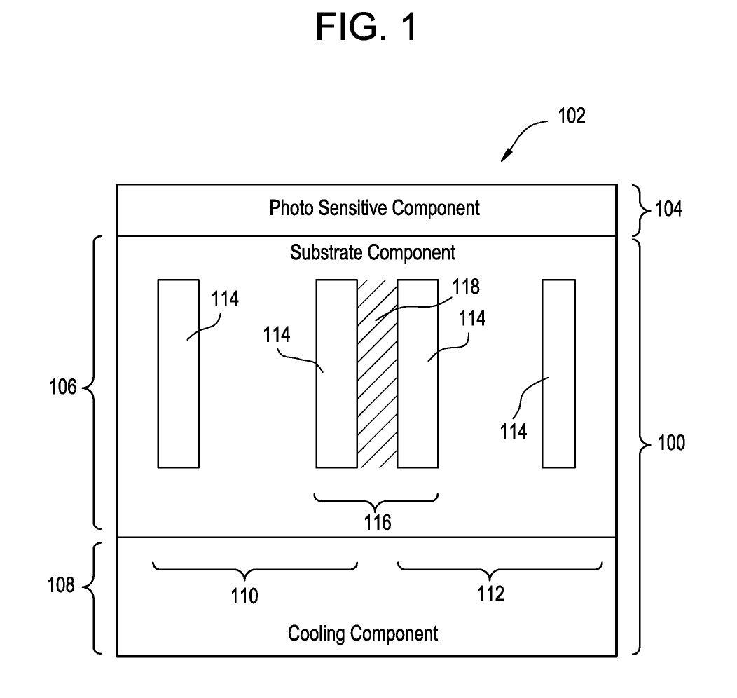

FIG. 1 illustrates a schematic diagram of an exemplary embodiment of a receiver component 100 that incorporates features to improve reliability and performance of power generating systems that utilize solar energy. The receiver component 100 is part of a power generating device 102, which includes a photosensitive component 104 that is disposed on the receiver component 100. Examples of the photosensitive component 104 can include one or more photosensitive devices, e.g., photovoltaic devices or cells that mount to the receiver component 100. As shown in FIG. 1, the receiver component 100 can include a substrate component 106 and a cooling component 108 that disperses cooling fluid proximate the substrate component 106. The substrate component 106 has one or more via structures (e.g., a first via structure 110 and a second via structure 112) that incorporate one or more via elements 114. The via structures 110, 112 can couple with the photosensitive component 104 to conduct signals (e.g., voltage, current, photocurrent, etc.) The substrate component 106 also includes a bypass element 116 that, in one example, includes a bypass region 118 disposed between one or more via structures 114.

Embodiments of the receiver component 100 maintain performance of the power generating device 102 to accommodate for uneven distribution of sunlight across the photosensitive component 104. In one embodiment, construction of the power generating device 102 electrically couples adjacent photosensitive devices. Use of the bypass element 116 enables current to pass between these adjacently-coupled photosensitive device during, for example, periods of no and/or low sunlight that can inhibit one or more of the photosensitive devices from generating photocurrent. Examples of the bypass element 116 can comprise a diode device and like elements and components that restrict (and/or prevent) current flow in a first direction and allow (and/or enable) current flow in a second direction that is different from the first direction. As shown in FIG. 1, the substrate component 106 can incorporate (and/or integrate) the diode device, for example, as embodied by a pair of via elements 114 (e.g., a first via element and a second via element) and the bypass region 120 disposed therebetween The bypass region 120 can connect the first via element and the second via element. In one example, the first via element and the second via element can couple with contacts found, respectively, on a first photosensitive device and a second sensitive device of the photosensitive component 104. In one example, the bypass region 120 can include one or more a P/N junctions, the construction of which is discussed further below.

The cooling component 108 utilizes cooling fluid to regulate temperature during operation of the photosensitive device 104. The combination of cooling fluid with electrical components runs counter to more typical heat dissipation theory (which uses large, thermally- conductive heat sinks and/or fans to move air). These conventional methodologies are designed to avoid shorting and other complications that fluids (e.g., water) can cause, e.g., during operation of the power generating device 102. Examples of the cooling component 108 can form one or more fluid paths and/or channels that allow cooling fluid to flow about the receiver component 100. In one example, the cooling component 108 can have an inlet and an outlet to allow ingress of relatively cold cooling fluid from an external fluid supply and egress of relatively warmer cooling fluid from the cooling component 108. This configuration can maintain continuous flow of the cooling fluid to maximize thermal dissipation.

Although discussed relative to photosensitive components, construction of the receiver component 100 can accommodate devices other than photosensitive devices discussed herein. Integration of the bypass element and use of the cooling component can prove advantageous for many devices (e.g., semiconductor devices, semiconductor-based lasers, light-emitting diode (LED) devices, etc.). To this end, examples of the substrate component 106 with integrated bypass element 116 can find use in other applications, e.g., for supporting and mounting of semiconductor chips, processors, and like semiconductor devices. These configurations find benefit in the use the functionality of the bypass element 106 as it relates to coupling of adjacent semiconductor devices as well as the improved cooling capabilities that incorporation of the cooling component 108 offer to the proposed designs.

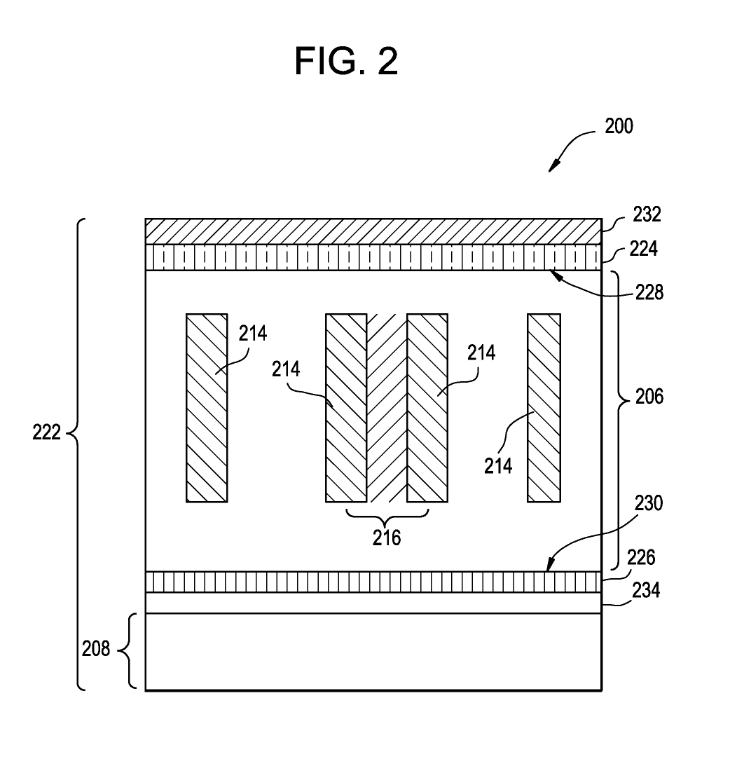

FIG. 2 illustrates a schematic diagram of an exemplary embodiment of a receiver component 200. In the example of FIG. 2, the receiver component 200 has a layered structure 222. Examples of the layered structure 222 can include one or more insulating layers (e.g., a first insulating layer 224 and a second insulating layer 226) disposed on, respectively, a first side 228 and a second side 230 of the substrate component 206. The layered structure 222 can also includes a conductive layer 232 that can couple with one or more of the via elements 214. In one embodiment, the layered structure 222 can further include a structural layer 234 that can incorporate features that facilitate connection with the cooling component 208.

Examples of the substrate component 206 can include a base substrate that comprises one or more semiconductor substrate materials (e.g., silicon, SiC, germanium, etc.). The base substrate can be manufactured using standard integrated circuit (IC) manufacturing equipment and techniques. In this way, the substrate component 206 can include various types of integrated circuitry and circuitry elements (e.g., diodes, transistors, resistors, capacitors) and structural elements (e.g., in the structural layer 234) that connect the substrate component 206 with the cooling component 208.

Processing of the base substrate can utilize photo-resist, which allows the via elements 214 to be etched and used as connections with the bypass element 216. Examples of the via elements 214 can comprise metal (e.g., copper, tungsten, etc.). In one example, the via elements 214 may also find use to mechanically align and/or couple the substrate component 206 with the cooling mechanism 208. Further processing of the base substrate, e.g., with photo-resist, can form the bypass element 216 as a diode (also “a bypass diode”). This processing can includes steps to implant a region of the base substrate with p-type and n-type dopants to form the diode. For example, the steps can deposit adjacent n-type and p-type layers on the back side (e.g., the second side 230) of the base substrate and place the via elements 214, filled with conductive material (e.g., metal) in relation to the corresponding n-type and p-type layers.

After deposition of material to form the via elements 214 and/or the bypass diode, the back side (e.g., the second side 230) of the base substrate can be coated with a di-electric material (e.g., SiO2, Si3N4, etc.) to form the second insulating layer 234. This di-electric material can electrically isolate the base substrate from the cooling component 206. Further processing steps can deposit one or more additional material layers (e.g., copper, aluminum, silver, etc.) to form the structural layer 234. Deposition of these material layers may utilize electroplating to thicken the structural layer 234. The resulting layer can couple the substrate component 206 with the cooling mechanism 208, e.g., using solder, brazing, or other techniques.

Additional processing steps can deposit a di-electric material (e.g., SiO2, Si3N4, etc.) on the front side (e.g., the first side 228) of the base substrate to form the first insulating layer 224. Portions of this di-electric material can be removed to form patterned openings, which conductive material (e.g., copper, aluminum, silver, etc.) of the conductive layer 232 can fill to form pads and/or other circuitry (e.g., electrical components, connections, etc.). This circuitry can conduct electrical signals and, in one construction, the circuitry may interconnect, e.g., with the by-pass diode in the substrate component 206.

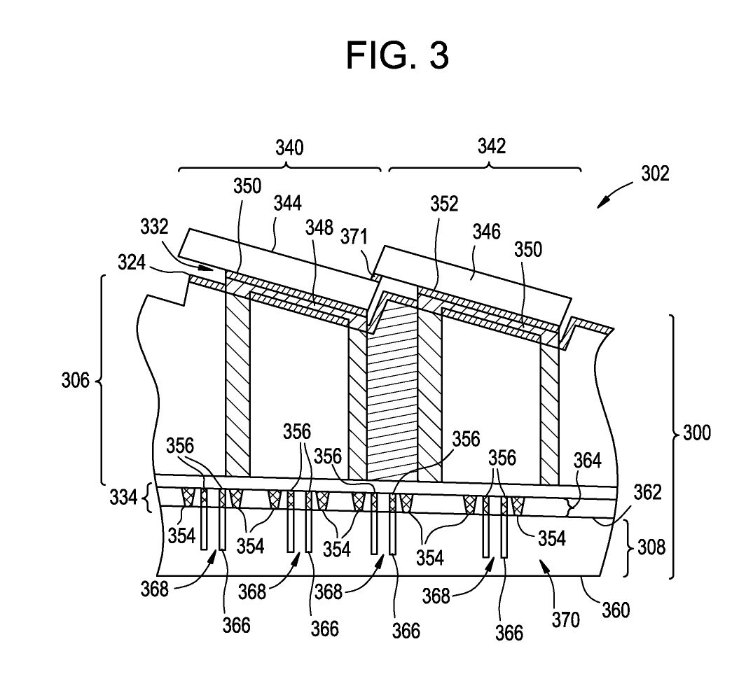

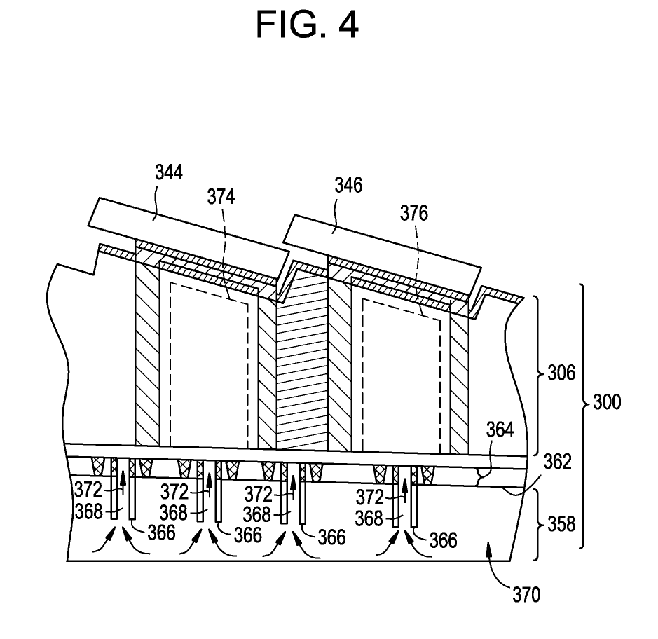

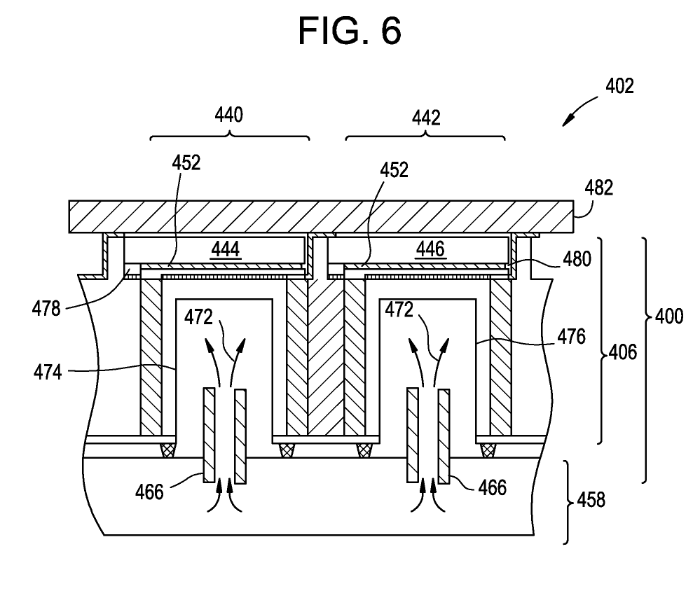

FIGS. 3, 4, 5, and 6 depict schematic, cross-section diagrams of exemplary embodiments of a receiver component 300 (FIGS. 3 and 4) and a receiver component 400 (FIG. 6). In FIG. 3, the substrate component 306 forms one or more mounting areas (e.g., a first mounting area 340 and a second mounting area 342). The mounting areas 340, 342 can receive and position the photosensitive device, shown in the example of FIG. 3 as a first photovoltaic device 344 and a second photovoltaic device 346. Examples of the power generating device 302 deploys the photovoltaic devices 344, 346 to convert light energy (e.g., sunlight) to electrical current (or power).

As also shown in FIG. 3, the conductive layer 332 forms one or more conductive pads (e.g., a first conductive pad 348 and a second conductive pad 350) in the mounting areas 340, 342. The receiver component 300 also includes a bonding element 352 to secure the photovoltaic devices 344, 346 to the corresponding conductive pad 348, 350. The structural layer 334 forms various structural elements (e.g., one or more first standoffs 354 and one or more second standoffs 356). The cooling component 308 includes a fluid distribution unit 358 with a lower member 360 and an upper member 362 that secures with the structural layer 334, e.g., with the first standoffs 354 and/or the second standoffs 356. This configuration forms a gap 364. In one example, the fluid distribution unit 358 also includes one or more nozzle elements 366 with a bore 368 that places the interior (e.g., interior 370) of the fluid distribution unit 358 in flow connection with the gap 364.

The front side (e.g., first side 228) of the base substrate can be patterned to form the mounting areas 340, 342. This pattern can be formed by removing material of the base substrate, e.g., by various techniques including mechanical (e.g., mechanical saw, laser, water jet, etc.) and chemical (e.g., etching). Di-electric material (e.g., SiO2, Si3N4, etc) forming the first insulating layer 334 can reside in the mounting areas 340, 342. In the present example, the mounting areas 340, 342 pitch and/or tilt the photovoltaic devices 344, 346. This configuration causes the second photovoltaic device 346 to overlap with the first photovoltaic device 344, thereby forming a “shingled” configuration. In one example, the device 302 can include a device connection (e.g., a device connection 371) that electrically couples the first photovoltaic device 344 to the second photovoltaic device 346.

During one manufacturing process, the photovoltaic device 344 can be mounted to the base substrate by depositing an interface medium (e.g., silver epoxy, solder, etc.) at the mounting area 340. The photovoltaic devices 344, 346 can be placed upon the interface medium, interconnection material can then be placed upon the mounting area 342, and the photovoltaic device 346 can be mounted in position. This process can continue until all mounting areas contain photovoltaic devices. As the photovoltaic devices are placed upon the corresponding mounting locations, the interconnecting medium will flow across the entire back-side of the photovoltaic cell while also flowing on top of the adjacent photovoltaic cell. Melting and cooling of the interconnection medium can make connections, e.g., on the bottom side of the photovoltaic device 346 and the top side of the photovoltaic device 344, thereby connecting a plurality of CPV cells in series (and/or forming a series circuit).

The structural layer 334 can comprise material that is patterned to form one or more of the standoffs 354, 356 using techniques often used to form one or more types of semiconductor copper pillars that form interconnects on semiconductor and semi-conductor based chips. Examples of the standoffs 354, 358 can fasten to the cooling mechanism 308, e.g., to the upper member 362, using a bonding agent (e.g., adhesive) and/or other fastening scheme (e.g., mechanical fasteners). Material for use as the standoffs 354, 356 may be conductive (e.g., metal) and/or non-conductive (e.g., di-electric). In one embodiment, the cooling mechanism 308 secures using solder that can be pre-tinned upon the standoffs 354, 356 and/or to other regions of the substrate component 306. This process can occur on the back side (e.g., the second side 236 of FIG. 2) of the base substrate. In one example, after solder deposition, the substrate component 306 can be aligned with one or more features on the cooling mechanism 306. In one example, the resulting assembly of components (e.g., the substrate component 306 and the cooling component 308) can be placed in an oven to cure the solder, thereby completing attachment.

Construction of the cooling component 306 can utilize various materials to form the cavity 370. This construction may form a monolithic unit, e.g., the lower member 360, the upper member 362, and any side walls or members (not shown) are formed as a single, contiguous unit. On the other hand, this disclosure contemplates construction of the fluid distribution unit 358 in multiple pieces, which are assembled and fastened together (using known techniques).

FIG. 4 illustrates a flow pattern for cooling fluid 372 that the fluid distribution unit 358 disperses to dissipate thermal energy from the receiver component 300. Examples of the cooling fluid can include gasses and liquids (e.g., water, refrigerants, etc.) The cooling fluid 372 circulates through the fluid distribution unit 358, e.g., in the cavity 370. The cooling fluid 372 can exit the cavity 370 through the bores 368, wherein the cooling fluid 372 enters the gap 364 and flows proximate the substrate component 306. In one example, the cooling mechanism 308 uses the substrate component 306 as a cap or top and one or more patterned lines (e.g., metal patterned lines) and/or apertures in the upper member 362 to channel the cooling fluid 372 back into the cooling component 306. This feature allows thermal energy from the substrate component 306 to dissipate into the cooling fluid 372. By allowing the cooling fluid 372 to flow and/or circulate, examples of the cooling component 308 can continue to effectively remove thermal energy and, thus, regulate the temperature of the substrate component 306 and the photoelectric devices 344, 346.

In one embodiment, the base substrate may incorporate one or more cavities (e.g., a first substrate cavity 374 and a second substrate cavity 376). The cavities 374, 376 can permit the cooling fluid 370 to penetrate into the substrate component 306. This configuration can dissipate more thermal energy from the substrate component 306. Examples of the cavities 374, 376 can be constructed to also permit the cooling fluid 370 to flow in closer proximity to the photoelectric devices 344, 346. This feature can more directly regulate the temperature to maintain operating efficiencies of the photoelectric devices 344, 346.

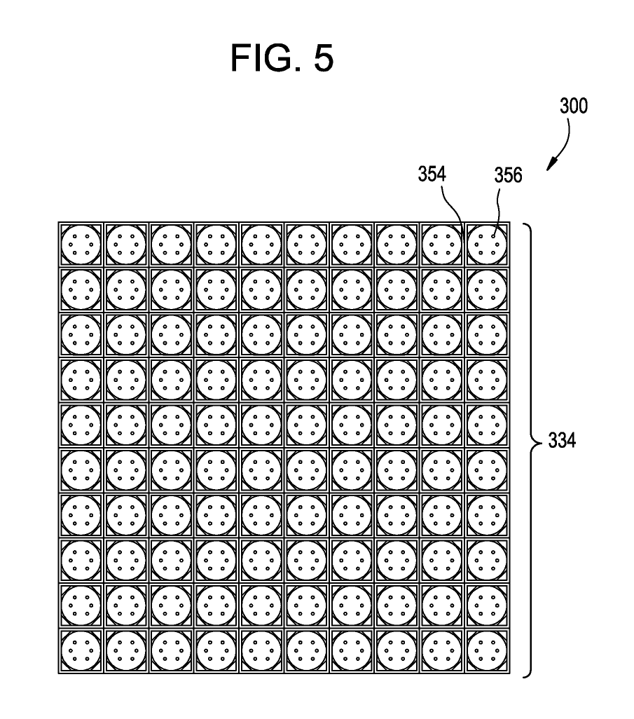

FIG. 5 depicts a bottom view of the receiver component 300 to illustrate one example of liquid flow pattern areas that help disperse cooling fluid throughout the receiver component 300. In the example of FIG. 5, the structural layer 334 (and/or base substrate) can permit delivery of the cooling fluid, e.g., from a location in the middle of standoffs 356. With the cooling component in position below the substrate component, the cooling fluid can contact the base substrate, exit through spaces between the standoffs 356, and return to the fluid distribution unit within the outside containment area 354 of the cooling array. In one example, standoffs 354, 356 will serve as mechanical interconnection locations to couple the substrate component with the cooling component.

In FIG. 6, the substrate component 406 can form one or more cavities (e.g., a first cavity 478 and a second cavity 480) to receive the photovoltaic cells 444, 446. The cavities 478, 480 orient the photovoltaic cells 444, 446 in a planar configuration. The nozzle elements 466 can direct the cooling fluid 470 into the cavities 472, 474. In one example, the fluid distribution unit 458 is configured to position to allow at least part of the nozzle elements 466 to extend into the cavities 472, 474. The energy converting device 402 can also include a cover component 482 that diffuses light to the photovoltaic cells 444, 446. Examples of the cover component 482 can comprises glass and diffusive plastics, as well as other materials that can diffuse light.

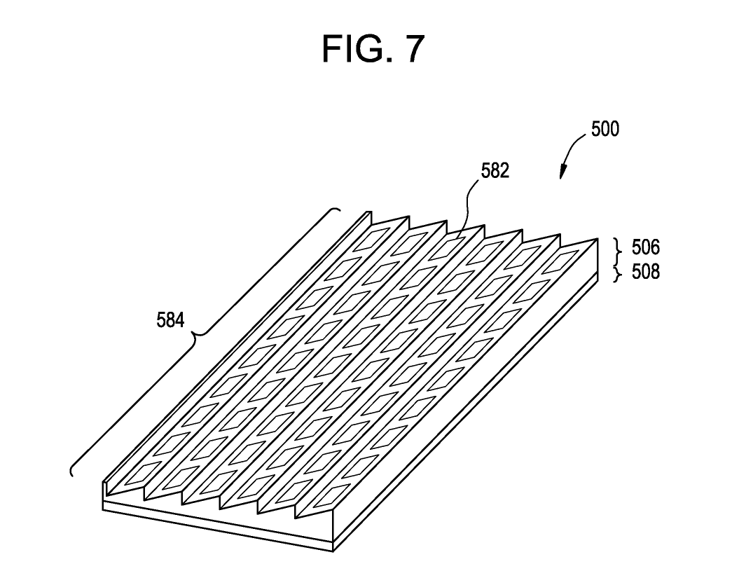

FIG. 7 illustrates a perspective view of an exemplary embodiment of a receiver component 500 that can accommodate a plurality of photovoltaic devices. The substrate component 506 has a plurality of mounting locations 582 that form a mounting array 584. This configuration can arrange the photovoltaic devices closely together. Energy conversion systems can take advantage of the density of the photovoltaic devices to generate electricity in a cost-effective manner. As disclosed herein, construction of the mounting array 584 couples the photovoltaic devices to the bypass elements, which are integrated into the substrate component 506. When the photovoltaic devices are in position, e.g., disposed and bonded at the mounting locations 582, the completed array 584 with integrated by-pass circuitry (e.g., bypass elements above) and cooling mechanism 508 can then be incorporated mechanically and with electrical interconnects to a CPV system. In one embodiment, the CPV system can comprises a plurality of the completed array 584, wherein construction of the CPV system can be scaled to meet size and/or output requirements as necessary.

As used herein, an element or function recited in the singular and proceeded with the word “a” or “an” should be understood as not excluding plural said elements or functions, unless such exclusion is explicitly recited. Furthermore, references to “one embodiment” of the claimed invention should not be interpreted as excluding the existence of additional embodiments that also incorporate the recited features.

This written description uses examples to disclose embodiments of the invention, including the best mode, and also to enable any person skilled in the art to practice the invention, including making and using any devices or systems and performing any incorporated methods. The patentable scope of the invention is defined by the claims, and may include other examples that occur to those skilled in the art. Such other examples are intended to be within the scope of the claims if they have structural elements that do not differ from the literal language of the claims, or if they include equivalent structural elements with insubstantial differences from the literal language of the claims.

What is claimed is:

1. A receiver component for receiving one or more semiconductor devices, said receiver component comprising:
a substrate component having a first mounting area and a second mounting area to receive the semiconductor device thereon and an bypass element formed therein, wherein the bypass element is configured to conduct current in one direction between the first mounting area and the second mounting area; and
a cooling component coupled with the substrate component, the cooling component comprising a fluid distribution unit that is configured to direct a cooling fluid proximate the substrate component.

2. The receiver component of claim 1, wherein the bypass element comprises a diode.

3. The receiver component of claim 1, wherein the substrate component comprises a base substrate with a first conductive via electrically coupled with the first mounting area, a second conductive via electrically coupled with the second mounting area, and a bypass region having one or more junction layers couple with the first conductive via and the second conductive via.

4. The receiver component of claim 3, wherein the junction layers comprise p-type and n-type dopants.

5. The receiver component of claim 1, wherein the first mounting area and the second mounting area have a surface that pitches at an angle.

6. The receiver component of claim 5, wherein the angle of the surface of the first mounting area is the same as the angle of the surface of the seconds mounting area.

7. The receiver component of claim 1, further comprising one or more standoffs disposed between the substrate component and an upper member of the fluid distribution unit, wherein the standoffs form a gap between the upper member and the substrate component.

8. The receiver component of claim 7, wherein the fluid distribution unit comprises one or more nozzle elements with a bore in flow connection with the gap.

9. The receiver component of claim 1, further comprising a dielectric layer disposed in the first mounting area and the second mounting area.

10. The receiver component of claim 1, further comprising a conductive layer disposed in the first mounting area and the second mounting area.

11. A receiver component, comprising:
a base substrate comprising a first mounting area and a second mounting area and a bypass element electrically coupled with the first mounting area and the second mounting area to conduct current in one direction between the first mounting area and the second mounting area,; and
a cooling component configured to disperse a cooling fluid proximate the base substrate.

12. The receiver component of claim 11, wherein the bypass element comprising a first conducive via, a second conductive via, and one or more p-type doped-layers and n-type doped layers coupled to the first conductive via and the second conductive via.

13. The receiver component of claim 11, further comprising an insulating layer and a metal layer disposed on the base substrate, wherein the cooling component couples with the metal layer

14. The receiver component of claim 13, wherein the metal layer forms one or more standoffs that secure to the cooling component to form a gap through which cooling fluid can flow.

15. An energy converting device, comprising:
a substrate comprising a bypass element that electrically couples a first photosensitive device and a second photosensitive device, the bypass element comprising a first conductive via electrically coupled with the firs photosensitive device, a second conductive via coupled with the second photosensitive device, and one or more junction layers coupled with the first conductive via and the second conductive via.

16. The energy converting device of claim 15, further comprising a cooling component with a nozzle element to flow a cooling fluid proximate the substrate.

17. The energy converting device of claim 15, further comprising a device connection that electrically couples a bottom surface of the first photosensitive device with a top surface of the second photosensitive device.

18. The energy converting device of claim 17, wherein the first photosensitive device and a second photosensitive device overlap to form a shingled configuration.

19. The energy converting device of claim 15, wherein the substrate forms mounting areas that arrange the first photosensitive device and the second photosensitive device in a planar configuration.

20. The energy converting device of claim 15, further comprising a cover element that diffuses light to the first photosensitive device and the second photosensitive device.
